(19) United States
(12) Patent Application Publication
(10) Pub. No.: US 2009/0101397 A1
(43) Pub. Date: Apr. 23, 2009

(54) PRINTED CIRCUIT BOARD HAVING IMPROVED SOLDER PAD LAYOUT

(75) Inventors: Nan-Sheng Kuo, Tu-Cheng (TW); Jung-Kuei Chung, Tu-Cheng (TW); Chu-Lung Chien, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/168,841

(22) Filed: Jul. 7, 2008

(30) Foreign Application Priority Data
Oct. 22, 2007 (CN) 200710202179.9

(51) Int. Cl. H05K 1/16; H05K 1/00

(52) U.S. Cl. 174/260; 174/250

(57) ABSTRACT

A printed circuit board (100) includes a plurality of through-holes (140) defined therein, a plurality of first solder pads (110) defined to surround the through-holes respectively, and a second solder pad (190). Each of the first solder pads includes a first soldering zone (112) for accommodating solder used in a soldering process and a second soldering zone (114) for receiving excess solder overflowing from the first soldering zone. The second soldering zone is in communication with and extends outward from the first soldering zone. The second solder pad is located on a tail end of the printed circuit board for receiving excess solder of the tail end during the soldering process.

### CROSS REFERENCE TO RELATED APPLICATION

Relevant subject matter is disclosed in a co-pending U.S. patent application Ser. No. 11/025,161, filed Dec. 29, 2004, entitled “PRINTED CIRCUIT BOARD HAVING IMPROVED SOLDER PAD LAYOUT”, assigned to the same assignee as this application.

### BACKGROUND OF THE INVENTION

1. Field of the Invention

The present invention relates to a printed circuit board, and specifically to a printed circuit board which has improved solder pad layout.

2. Description of Related Art

A typical electrical device generally comprises a printed circuit board (PCB) on which a plurality of components, such as resistors, capacitors, Dual In-line Package (DIP) components, etc., is mounted. The components are generally mounted to the printed circuit board by inserting component pins into through-holes defined in the printed circuit board, and later being soldered to the printed circuit board in a soldering process.

Nowadays, electrical devices are getting smaller, and the components inserted into the printed circuit boards are also getting smaller. For DIPs, spacing between the pins is getting smaller; some pin spacing is less than 1.27 millimeters. Therefore, the structure of printed circuit boards must be changed to meet this situation.

Referring to FIGS. 6 and 7, these figures illustrate a typical printed circuit board 1 which will be processed through a wave-soldering machine (not shown) for soldering a component 2 thereto. The component 2 comprises a plurality of pins 8, 9. A plurality of through-holes 6 is defined in the printed circuit board 1 for holding the pins 8, 9 respectively. A plurality of solder pads 3, 5 is defined in the printed circuit board 1 to surround through-holes 6 respectively. Each of the solder pads 3, 5 is circular. The pins 8, 9 of the component 2 are extended through the printed circuit board 1 via corresponding through-holes 6. Solder is applied to the solder pads 5. The printed circuit board 1 is passed through the wave-soldering machine, and excess molten solder spread out from the solder pads 5 to form a bridge 4 between adjacent pins 8, 9. A shorting is thus produced between the pin 8 and the pin 9, and the printed circuit board can be damaged in use due to the shorting.

Therefore, a heretofore unaddressed need exists in the industry to overcome the aforementioned deficiencies and inadequacies.

### SUMMARY OF THE INVENTION

In one exemplary embodiment, a printed circuit board includes a plurality of through-holes defined therein, a plurality of first solder pads defined to surround the through-holes respectively, and a second solder pad. Each of the first solder pads includes a first soldering zone for accommodating solder used in a soldering process and a second soldering zone for receiving excess solder overflowing from the first soldering zone. The second soldering zone is in communication with and extends outward from the first soldering zone. The second solder pad is located on a tail end of the printed circuit board for receiving excess solder received on the tail end during the soldering process.

Other advantages and novel features will become more apparent from the following detailed description when taken in conjunction with the accompanying drawings, in which:

### BRIEF DESCRIPTION OF THE DRAWINGS

FIG. 1 is an exploded, isometric view of a printed circuit board and a component according to a first embodiment of the present invention;

FIG. 2 is an enlarged view of a circled portion II of FIG. 1

FIG. 3 is an assembled view of FIG. 1;

FIG. 4 is an isometric view of a printed circuit board according to a second embodiment of the present invention; and

FIG. 5 is an assembled view of FIG. 4;

FIG. 6 is an exploded, isometric view of a printed circuit board and a component according to the related art; and

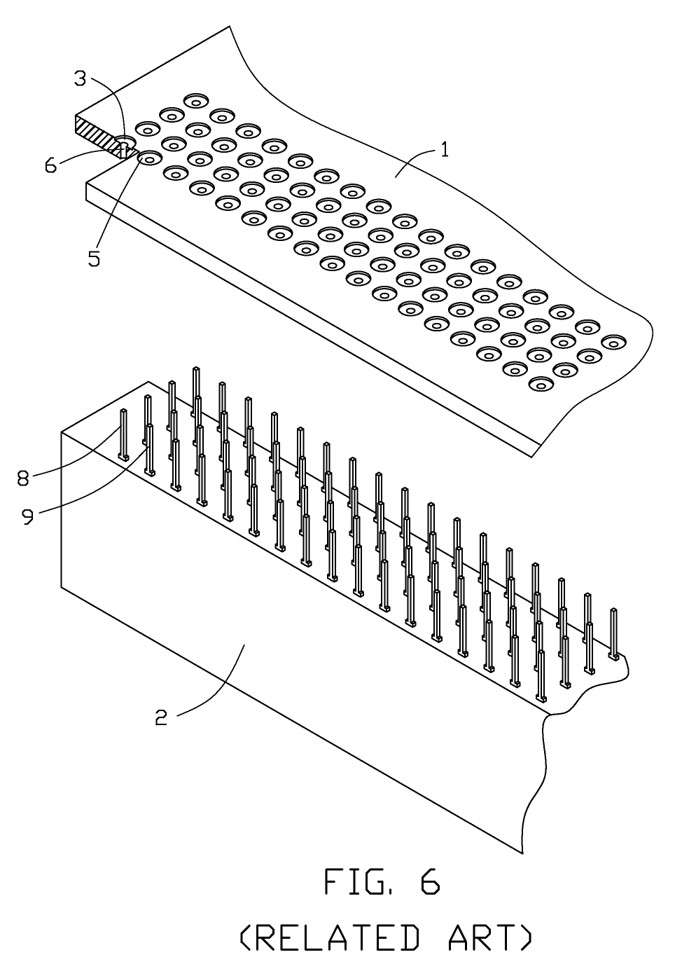

FIG. 7 is an assembled view of FIG. 6.

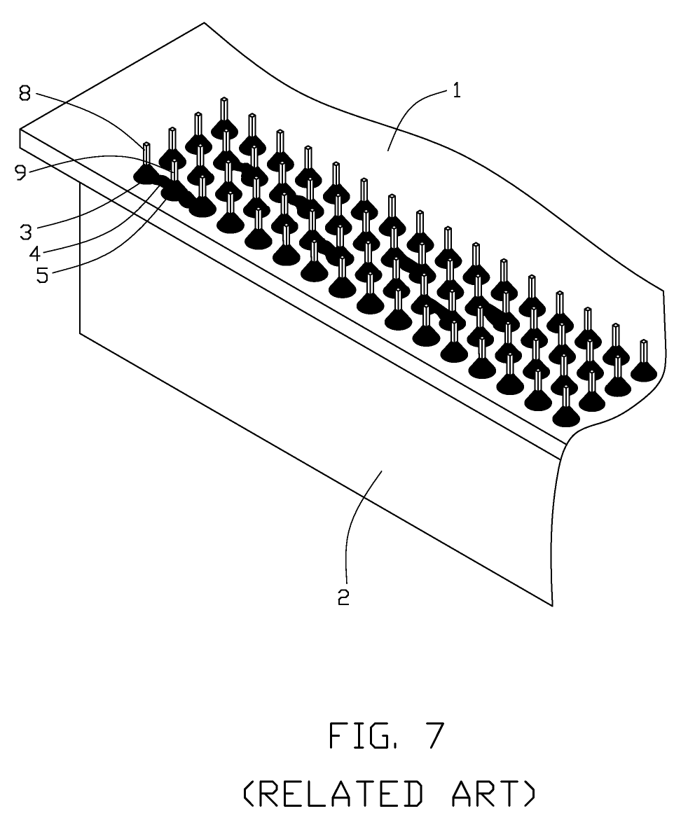

### DETAILED DESCRIPTION OF THE INVENTION

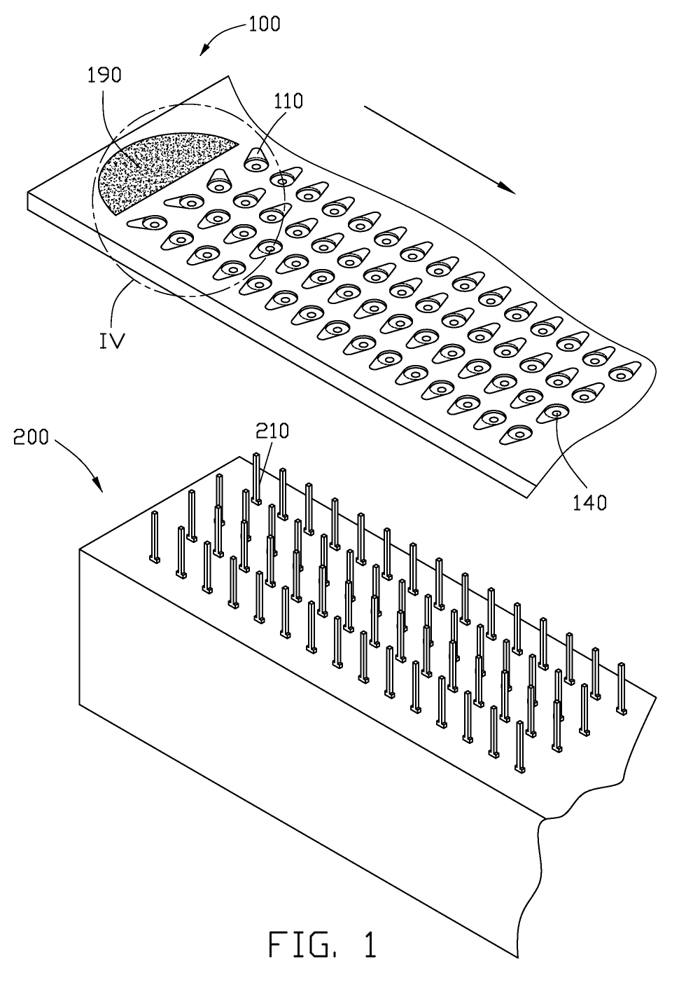

Referring to FIG. 1, a printed circuit board 100 and a component 200 of the first embodiment of the present invention are shown. The printed circuit board 100 defines a plurality of electrically conductive first solder pads 110 and a second solder pad 190, and a plurality of through-holes 140. An area of the second solder pad 190 is greater than that of any one of the first solder pads 110. The first solder pads 110 surround the through-holes 140 respectively. The second solder pad 190 is located at a tail end of the printed circuit board 100. The component 200 comprises a plurality of pins 210 arranged in rows and columns, and are received in the corresponding through-holes 140 of the printed circuit board 100. In the embodiment, the pins 210 arranged in one column located at a tail end of the component 200 are designated as first pins 210, the pins 210 arranged in one column adjacent to the first pins 210 are designated as second pins 210.

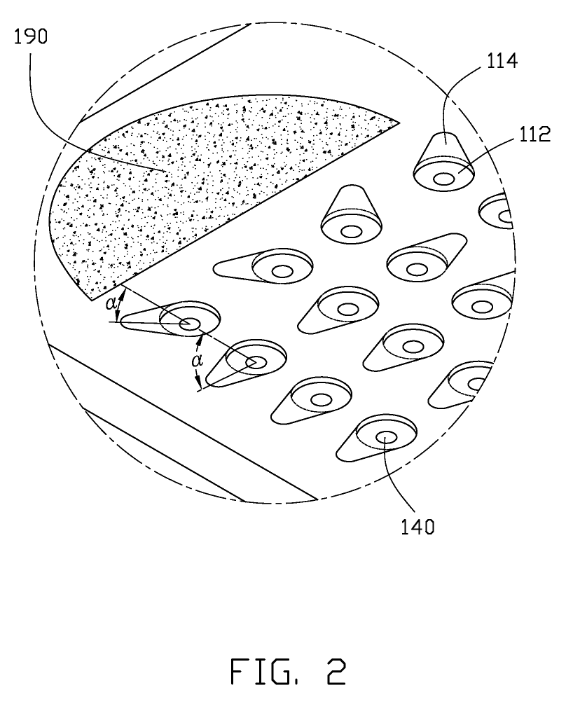

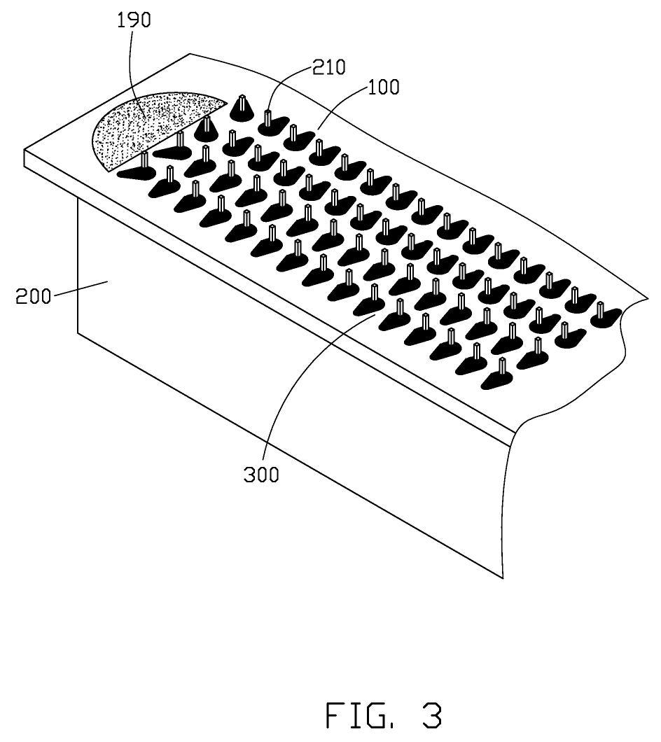

Referring also to FIG. 2, each of the first solder pads 110 is capable of being soldered, and is tear-shaped. Each of the first solder pads 110 comprises a first soldering zone 112 for accommodating solder 300 (Referring to FIG. 3) used in a solder process, and a second soldering zone 114 in communication with and extending outward from the first soldering zone 112 for receiving excess solder overflowing from the first solder zone 112. The second soldering zone 114 of each of the first solder pads 110 is arcuate shaped. Each through-hole 140 is located at a middle portion of the first soldering zone 112. The first solder pads 110 are arranged in rows and columns, and the second soldering zone 114 of each of the first solder pads 110 arranged in one row defines a same extending direction. The extending direction of the second soldering zone 114 of each of the first solder pads 110 arranged in one row located in a first end side of the printed circuit board is different from the extending direction of the second soldering zone 114 of each of the first solder pads 110 arranged in one row located in a second end side of the printed circuit board opposite to the first end side. In the embodiment, the first solder pads 110 arranged in one column adjacent to the second solder pad 190 are designated as tail first solder pads 110.

The direction of movement of the printed circuit board 100 in the wave-soldering machine (not shown) as indicated by an arrow shown in FIG. 1 is designated as a first direction. A direction opposite to the movement direction of the printed circuit board 100 is designated as a second direction. An axis of each second soldering zone 114 of the first solder pad 110 and the second direction cooperatively define an angle alpha. Each of the first solder pads 110 arranged in one row defines a same angle alpha. The angle alpha ranges between 15 degrees to 90 degrees. In the embodiment, the angle alpha of each of the tail first solder pads 110 is 45 degrees, the angle alpha of each of the other first solder pads 110 is 90 degrees.

The second solder pad 190 is fan-shaped. A central axis of the second solder pad 190 is aligned with a horizontal central line of a region surrounded by the first solder pads 110. A central angle of the second solder pad 190 ranges between 120 degrees and 180 degrees.

Referring also to FIG. 3, to solder the component 200 to the printed circuit board 100, the pins 210 of the component 200 are extended through the through-holes 140 of the printed circuit board 100, and the solder 300 is fed to the first soldering zones 112 of the first solder pads 110 respectively. The printed circuit board 100 with the component 200 is passed through a wave-soldering machine via a transport belt (not shown). When the printed circuit board 100 is carried to move slantingly upward in the wave-soldering machine, excess molten solder in the first soldering zones 112 of the first solder pads 110 flows toward the second direction because of gravity, that is, the excess molten solder flows into the second soldering zones 114 of the first solder pads 110 respectively. In this way, it will prevent adjacent pins 210 from being soldered together by the excess solder, so electrical shorting between the adjacent pins 210 is thus prevented. And, excess molten solder in the tail end of the printed circuit board 100 flows into the second solder pad 190, that is, bridging by excess solder between the adjacent first pins 210 and between the first pins 210 and the second pins 210 is prevented, and electrical shorting between adjacent first pins 210 and between the first pins 210 and the second pins 210 is thus prevented.

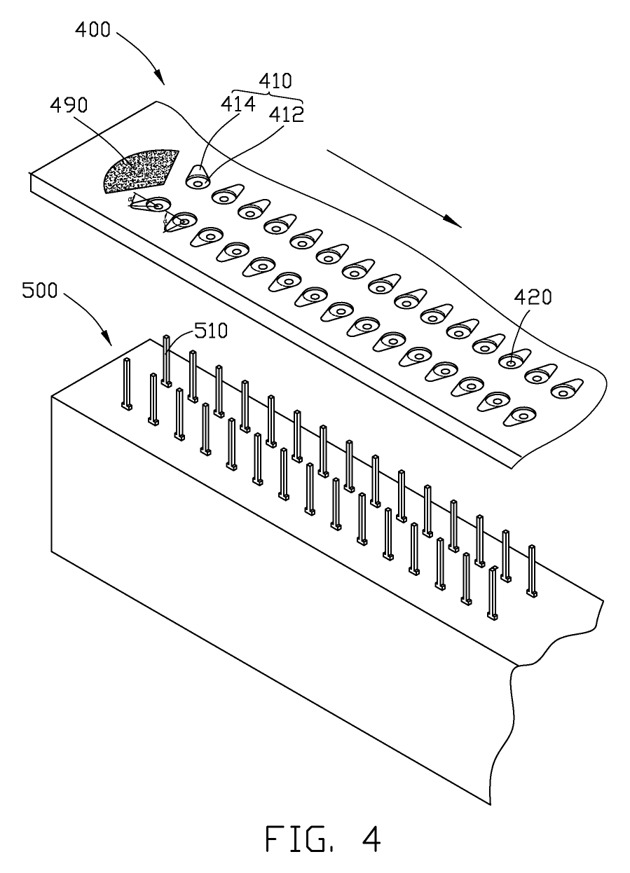

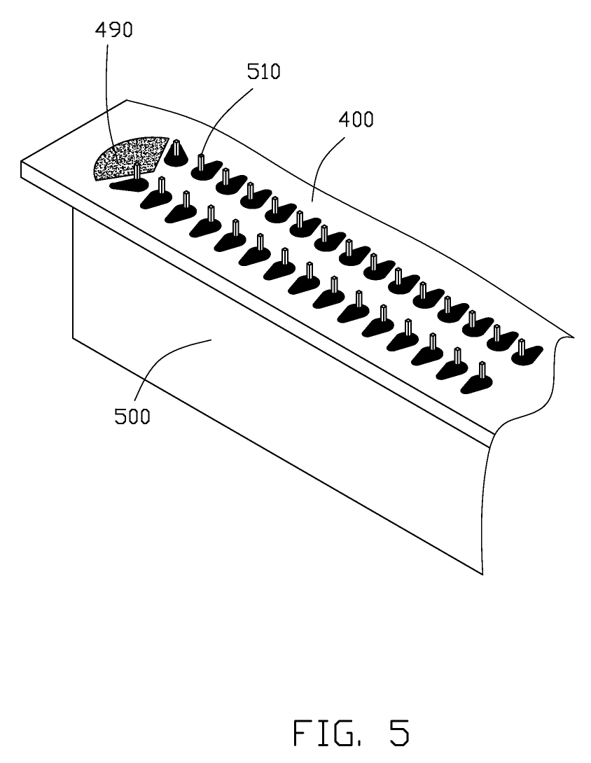

Referring to FIGS. 4 and 5, a printed circuit board 400 and a component 500 of the second embodiment of the present invention are shown. The printed circuit board 400 defines a plurality of through-holes 420, a plurality of first solder pads 410 surrounding the through-holes 420 respectively, and a second solder pad 490 located at a tail end thereof. The through-holes 420 are arrayed in two rows, and the first solder pads 410 are correspondingly arranged in two rows. Each of the first solder pads 410 comprises a first soldering zone 412 and a second soldering zone 414 in communication with the first soldering zone 412 and extending outward from the first soldering zone 412. The second soldering zone 414 of each of the first solder pads 410 arranged in one row defines a same extending direction. The extending direction of the second soldering zones 114 of the first solder pads 110 arranged in one row is different from the extending direction of the second soldering zones 114 of the first solder pads 110 arranged in another row. A central angle of the second solder pads 490 is 120 degrees. Other elements of the printed circuit board 400 are similar to the printed circuit board 100 as shown in FIG. 1, and the printed circuit board 400 can perform the same function as the printed circuit board 100. The component 500 comprises two rows of pins 510. Other elements of the component 500 are similar to the component 200 as shown in FIG. 1, and the component 500 can perform the same function as the component 200.

While exemplary embodiments have been described above, it should be understood that they have been presented by way of example only and not by way of limitation. Thus the breadth and scope of the present invention should not be limited by the above-described exemplary embodiments, but should be defined only in accordance with the following claims and their equivalents.

What is claimed is:

1. A printed circuit board, comprising:
a plurality of through-holes defined therein;
a plurality of first solder pads configured to surround the through-holes respectively, each of the first solder pads comprising a first soldering zone for accommodating solder used in a soldering process and a second soldering zone for receiving excess solder overflowing from the first soldering zone, the second soldering zone in communication with and extending outward from the first soldering zone; and
a second solder pad located on a tail end thereof for receiving excess solder of the tail end during the soldering process.

2. The printed circuit board of claim 1, wherein an axis of each of the first solder pads and a direction opposite to a movement direction of the printed circuit board in the soldering process defines a predetermined angle.

3. The printed circuit board of claim 2, wherein each of the first solder pads defines a same angle ranging from 15 degrees to 90 degrees.

4. The printed circuit board of claim 1, wherein the first solder pads are arranged in rows, the second soldering zone of each of the first solder pads arranged in one row adjacent to one end side of the printed circuit board defines a same first extending direction, and each of the first solder pads arranged in another row adjacent to another end side of the printed circuit board opposite to said end side defines a same second extending direction different from the first extending direction.

5. The printed circuit board of claim 1, wherein the second soldering zone of each of the first solder pads is arcuate shaped.

6. The printed circuit board of claim 1, wherein the second solder pad is fan-shaped.

7. The printed circuit board of claim 5, wherein a central angle of the second solder pad ranges from 120 degrees to 180 degrees.

8. The printed circuit board of claim 1, wherein an area of the second solder pad is greater than any one of the first solder pads.

9. An assembly comprising:
a component with a plurality of pins symmetrically distributed at one side of said component with respect to a central line of said side;
a circuit board configured to electrically mount said component thereon and abut against said side of said component, a plurality of through-holes defined in said circuit board to allow said plurality of pins correspondingly passing therethrough, a plurality of first solder pads defined on a side of said circuit board facing away from said component to respectively surround said plurality of through-holes, each of said plurality of first solder pads comprising a first soldering zone surrounding a corresponding one of said plurality of through-holes for accommodating a desired amount of solder thereon in a soldering process, and a second soldering zone extending out of said first soldering zone along a direction perpendicular to said central line of said side of said component for accommodating excess solder from said first soldering zone thereon in said soldering process.

10. The assembly of claim 9, wherein said circuit board further comprises a second solder pad located beside said plurality of first solder pads so as to accommodate excess solder during said soldering process, said second solder pad occupies an area on said circuit board wider than an occupied area of at least two of said plurality of first solder pads.

11. The assembly of claim 9, wherein said first solder pads are arranged in rows, said second soldering zone of each of said first solder pads arranged in one row adjacent to one end of said side of said printed circuit board defines a same first extending direction, and each of said first solder pads arranged in another row adjacent to another end of said side of said printed circuit board opposite to said end defines a same second extending direction different from said first extending direction.

12. A printed circuit board, comprising:
a plurality of through-holes defined therein;
a plurality of first solder pads symmetrically distributed at a side of the printed circuit board about a central line of the side to surround the through-holes respectively, each of the first solder pads comprising a first soldering zone for accommodating a desired amount of solder thereon in a soldering process and a second soldering zone for receiving excess solder during the soldering process, the second soldering zone in communication with and extending outward from the first soldering zone, an axis of each of the second soldering zone and the central line cooperatively defining an angle; and
a second solder pad located on a tail end thereof for receiving excess solder of the tail end during the soldering process;
wherein the angle of the second sildering zone of each of the first solder pads arranged in one column adjacent to the second solder pad is different from the angle of the second sildering zone of each of the first solder pads arranged in other columns.

13. The printed circuit board of claim 12, wherein the angle of the second sildering zone of each of the first solder pads arranged in one column adjacent to the second solder pad is 45 degrees.

14. The printed circuit board of claim 13, wherein the angle of the second sildering zone of each of the first solder pads arranged in other columns is 90 degrees.
